(19) United States
(12) Patent Application Publication
(10) Pub. No.: US 2014/0063963 A1
(43) Pub. Date: Mar. 6, 2014

(54) SEMICONDUCTOR MEMORY DEVICE

(71) Applicant: KABUSHIKI KAISHA TOSHIBA, Tokyo (JP)

(72) Inventors: Xu Li, Yokohama-shi (JP); Kiyotaro Itagaki, Naka-gun (JP); Ryo Fukuda, Yokohama-shi (JP)

(73) Assignee: KABUSHIKI KAISHA TOSHIBA, Tokyo (JP)

(21) Appl. No.: 13/830,975

(22) Filed: Mar. 14, 2013

(30) Foreign Application Priority Data
Sep. 4, 2012 (JP) 2012-194159

(51) Int. Cl. G11C 16/06

(52) U.S. Cl. CPC G11C 16/06
USPC 365/185.17; 365/185.18

(57) ABSTRACT

According to one embodiment, a semiconductor memory device includes a memory core including a memory cell array, and a peripheral circuit configured to transfer data input to a pad unit to the memory core, and transfer data transferred from the memory core to the pad unit. The peripheral circuit includes a first region including a first data bus having a first wiring resistance, and a second region including a second data bus having a second wiring resistance lower than the first wiring resistance. The first region transfers data parallel at a first operating speed, and the second region serially transfers data at a second operating speed higher than the first operating speed.

### CROSS-REFERENCE TO RELATED APPLICATIONS

This application is based upon and claims the benefit of priority from Japanese Patent Application No. 2012-194159, filed Sep. 4, 2012, the entire contents of which are incorporated herein by reference.

### FIELD

Embodiments described herein relate generally to a semiconductor memory device.

### BACKGROUND

A NAND flash memory is known as a kind of electrically programmable nonvolatile semiconductor memory devices. To increase the bit density of this NAND flash memory, a multilayered structure of memory cells is regarded as promising because the micropatterning technologies have become close to their limits. As an example, a stacked NAND flash memory in which memory cells are formed using vertical transistors has been proposed.

In the stacked NAND flash memory, the sectional area of an interconnect used as a bit line is decreased in order to reduce the capacitance of the bit line. Consequently, the wiring resistance of the bit line increases. When a high-resistance interconnect is used as a data bus in a peripheral circuit for transferring data through a bit line, a large wiring delay occurs. Especially in a semiconductor memory such as this stacked NAND flash memory in which the size of a peripheral circuit is large, the length of a high-resistance interconnect increases, and this is disadvantageous to increase the speed of a data bus.

### BRIEF DESCRIPTION OF THE DRAWINGS

FIG. 1 is a block diagram of a NAND flash memory according to the first embodiment;

FIG. 2 is a circuit diagram of a block included in a memory cell array;

FIG. 3 is a sectional view of the memory cell array;

FIG. 4 is a view for explaining the arrangement of data buses of the NAND flash memory according to the first embodiment;

FIG. 5 is a circuit diagram showing an example of a shift register;

FIG. 6 is a circuit diagram showing an example of a three-state buffer;

FIG. 7 is a circuit diagram showing an example of a latch circuit;

FIG. 8 is a view for explaining data flows in the shift register when data is input;

FIG. 9 is a timing chart showing the data input operation of the NAND flash memory;

FIG. 10 is a view for explaining data flows in the shift register when data is output;

FIG. 11 is a timing chart showing the data output operation of the NAND flash memory;

FIG. 12 is a view for explaining the arrangement of data buses of a NAND flash memory according to the second embodiment;

FIG. 13 is a view for explaining the arrangement of data buses of a NAND flash memory according to the third embodiment;

FIG. 14 is a sectional view for explaining a layout example of a peripheral circuit;

FIG. 15 is a circuit diagram showing an example of a shift register;

FIG. 16 is a view for explaining data flows in the shift register when data is input;

FIG. 17 is a timing chart showing the data input operation of the NAND flash memory;

FIG. 18 is a view for explaining data flows in the shift register when data is output;

FIG. 19 is a timing chart showing the data output operation of the NAND flash memory; and

FIG. 20 is a view for explaining the arrangement of data buses of a NAND flash memory according to a comparative example.

### DETAILED DESCRIPTION

In general, according to one embodiment, there is provided a semiconductor memory device comprising:

a memory core including a memory cell array; and

a peripheral circuit configured to transfer data input to a pad unit to the memory core, and transfer data transferred from the memory core to the pad unit,

wherein the peripheral circuit includes a first region including a first data bus having a first wiring resistance, and a second region including a second data bus having a second wiring resistance lower than the first wiring resistance,

the first region transfers data parallel at a first operating speed, and

the second region serially transfers data at a second operating speed higher than the first operating speed.

Embodiments will be explained below with reference to the accompanying drawings. Note that these drawings are exemplary or conceptual, so the dimensions and ratios of each drawing are not necessarily the same as real dimensions and ratios. Several embodiments to be described below represent examples of apparatuses and methods for embodying the technical idea of the present invention, and the technical idea of the present invention is not specified by the shapes, structures, and layouts of the constituent parts. Note that in the following explanation, the same reference numerals denote elements having the same functions and arrangements, and a repetitive explanation will be made only when necessary.

### First Embodiment

A semiconductor memory device will be explained below by taking a three-dimensional stacked type NAND flash memory in which a plurality of memory cells are stacked on a substrate as an example.

### [1] Arrangement of Semiconductor Memory Device

First, the arrangement of the semiconductor memory device (NAND flash memory) according to this embodiment will be explained.

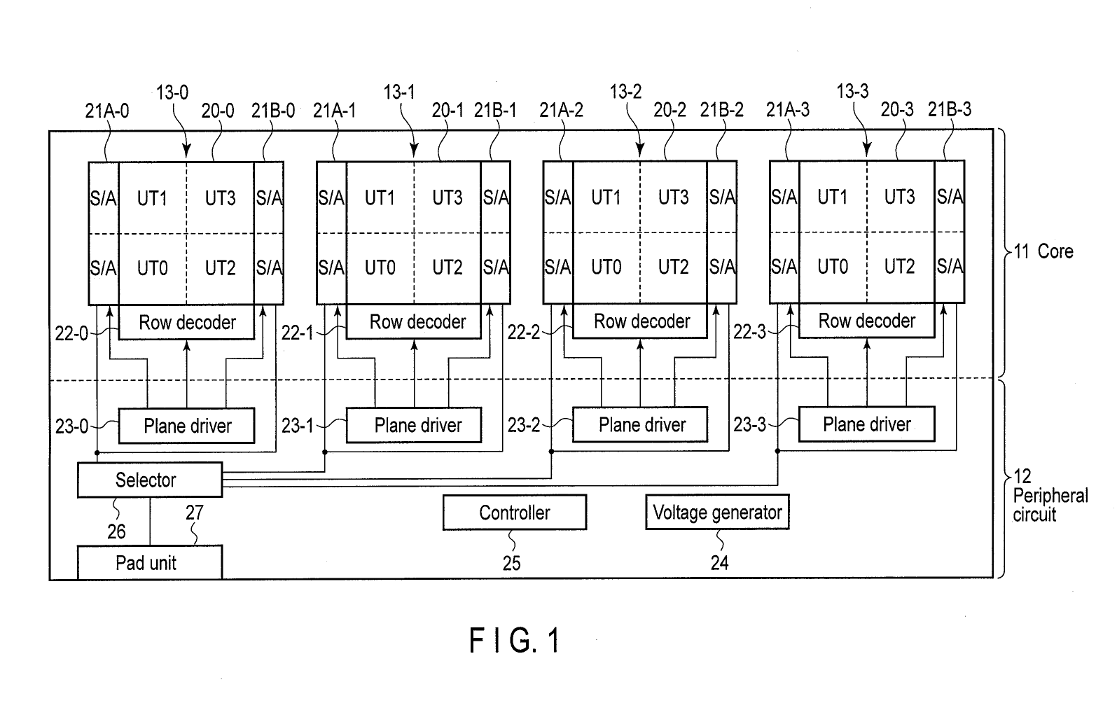

FIG. 1 is a block diagram of the NAND flash memory according to the first embodiment. This NAND flash memory includes a core (memory core) 11 as a data storage unit, and a peripheral circuit 12 for controlling the core 11.

The core 11 includes a plurality of planes 13.

This embodiment will be explained by taking four planes 13-0 to 13-3 as an example, but the number of planes 13 can be freely set. The plane 13-0 includes a memory cell array 20-0, sense amplifiers (S/As) 21A-0 and 21B-0, and a row decoder 22-0. The planes 13-1 to 13-3 each have the same arrangement as that of the plane 13-0. Note that in the following explanation, the planes 13-0 to 13-3 will simply be referred to as planes 13 if it is not particularly necessary to distinguish between them, and the same shall apply to the internal circuits of the planes.

The memory cell array 20 includes, for example, four units UT0 to UT3. Each unit UT includes a plurality of blocks BLK. Each block BLK includes a plurality of nonvolatile memory cells, and data in the same block BLK are erased at once.

The row decoder 22 performs selection in the row direction of the memory cell array 20. Also, when writing, reading, and erasing data, the row decoder 22 applies various voltages to word lines, select gate lines, and backgate lines formed in the memory cell array 20.

Sense amplifier 21A is formed to correspond to units UT0 and UT1. Sense amplifier 21A controls the voltages of bit lines formed in units UT0 and UT1. When reading data, sense amplifier 21A senses and amplifies the data read from a memory cell. When writing data, sense amplifier 21A transfers write data to a memory cell. Sense amplifier 21B is formed to correspond to units UT2 and UT3. The operation of sense amplifier 21B is the same as that of sense amplifier 21A.

Next, the arrangement of the peripheral circuit 12 will be explained. The peripheral circuit 12 includes plane drivers 23-0 to 23-3, a voltage generator 24, a controller 25, a selector 26, and a pad unit 27.

The plane drivers 23-0 to 23-3 are formed to respectively correspond to the planes 13-0 to 13-3. The plane driver 23 controls the plane 13 when writing, reading, and erasing data. The voltage generator 24 generates various voltages necessary for operations (write, read, and erase operations) of the NAND flash memory, and applies the various voltages to the plane drivers 23-0 to 23-3.

The pad unit 27 includes a plurality of pads. The pad unit 27 exchanges (receives and transmits) data with an external circuit (for example, a host apparatus), and receives power from the external circuit. When data is input from the external circuit to the pad unit 27, the selector 26 supplies the input data to a data bus for a selected plane. Also, when data is output from a selected plane, the selector 26 supplies the output data to the pad unit 27.

The controller 25 controls the operation of the whole NAND flash memory. To perform this control, the controller 25 supplies various control signals to the individual circuits of the NAND flash memory.

### [1-1] Arrangement of Memory Cell Array 20

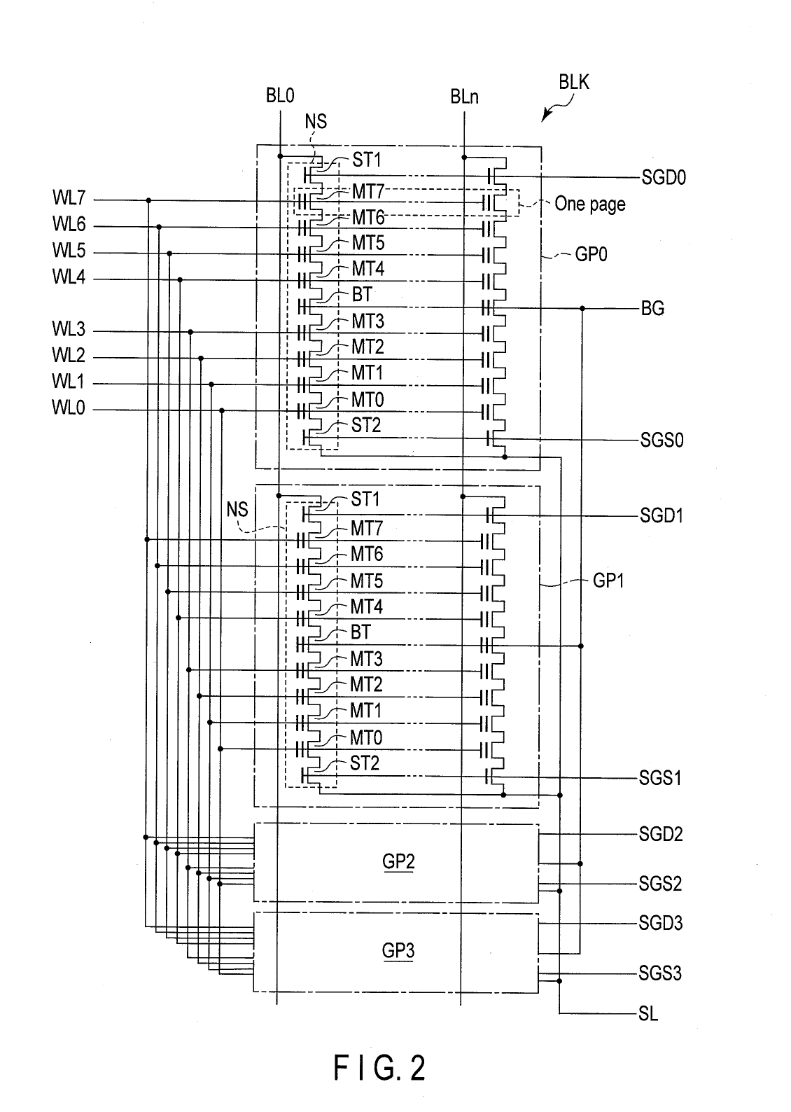

The arrangement of the memory cell array 20 will be explained below. As described above, the memory cell array 20 (more specifically, each unit UT) includes the plurality of blocks BLK. FIG. 2 is a circuit diagram of one block BLK.

The block BLK includes a plurality of memory groups GP. This embodiment will be explained by taking an arrangement in which one block BLK includes four memory groups GP0 to GP3 as an example, but the number of memory groups GP can be freely set. Each memory group GP includes n (n is a natural number) NAND strings NS.

Each NAND string NS includes, for example, eight memory cell transistors MT (MT0 to MT7), two select transistors ST1 and ST2, and a backgate transistor BT. Each memory cell transistor MT includes a multilayered gate including a control gate and charge storage layer, and nonvolatilly stores data. Note that the number of memory cell transistors MT is not limited to 8, and can also be, for example, 16, 32, 64, or 128, i.e., the number can be freely set. Similar to the memory cell transistor MT, the backgate transistor BT includes a multilayered gate including a control gate and charge storage layer. The backgate transistor BT does not store data, and is turned on when writing, reading, and erasing data.

The memory cell transistors MT and backgate transistor BT are arranged between the select transistors ST1 and ST2, so as to connect their current paths in series. The backgate transistor BT is formed between the memory cell transistors MT3 and MT4. The current path of the memory cell transistor MT7 at one end of this series connection is connected to one end of the current path of the select transistor ST1. The current path of the memory cell transistor MT0 at the other end of the series connection is connected to one end of the current path of the select transistor ST2.

The gates of the select transistors ST1 of each of the memory groups GP0 to GP3 are connected together to a corresponding one of select gate lines SGDO to SGD3. The gates of the select transistors ST2 of each of the memory groups GP0 to GP3 are connected together to a corresponding one of select gate lines SGS0 to SGS3. The control gates of the memory cell transistors MT0 to MT7 in the same block BLK are respectively connected together to word lines WL0 to WL7. The control gates of the backgate transistors BT in the same block BLK are connected together to a backgate line BG.

That is, the plurality of memory groups GP in the same block BLK share the word lines WL0 to WL7 and backgate line BG, but the select gate lines SGD and SGS are formed for each memory group GP even in the same block BLK.

Of the NAND strings NS arranged in a matrix in the memory cell array 20, the other-end sides of the current paths of the select transistors ST1 of the NAND strings NS in the same row are connected together to one of n (n is a natural number) bit lines BL (BLO to BLn). That is, the bit lines BL connect the NAND strings NS together between the plurality of blocks BLK. Also, the other-end sides of the current paths of the select transistors ST2 are connected together to a source line SL. The source line SL connects the NAND strings NS together between, for example, the plurality of blocks BLK.

As described previously, data in the memory cell transistors MT in the same block BLK are erased at once. By contrast, data read or write is performed at once to a plurality of memory cell transistors MT connected together to a given word line WL in a given memory cell group GP. This unit will be called a page.

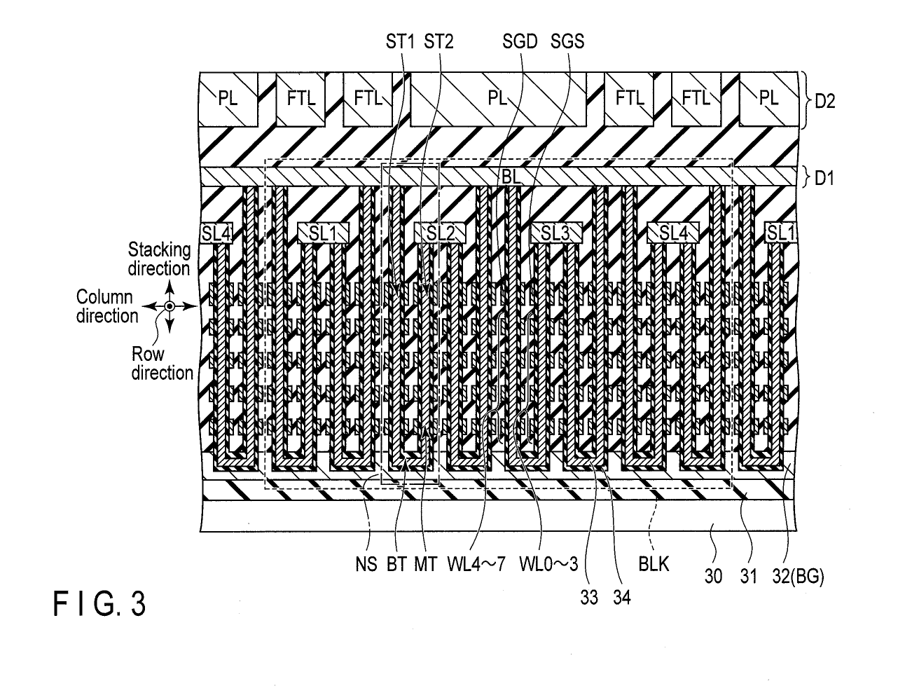

FIG. 3 is a sectional view of the memory cell array 20. FIG. 3 shows a section taken along the column direction of the memory cell array 20.

The memory cell array 20 is formed on an insulating layer 31 on a semiconductor substrate 30. Each block BLK included in the memory cell array 20 includes a plurality of NAND strings NS.

The NAND string NS includes a U-shaped semiconductor layer 33. That is, the semiconductor layer 33 includes a pair of columnar portions extending perpendicularly to the surface of the semiconductor substrate 30, and a connecting portion for connecting the lower ends of the pair of columnar portions. The semiconductor layer 33 has one end connected to the bit line BL, and the other end connected to the source line SL. The semiconductor layer 33 functions as the body (channel formation portion) of the NAND string NS.

An insulating layer 34 is formed to surround the semiconductor layer 33. The insulating layer 34 is obtained by stacking a tunnel insulating film, charge storage layer, and block insulating film in this order from the semiconductor layer 33. The tunnel insulating film and block insulating film are made of, for example, silicon oxide (SiO₂). The charge storage layer is made of, for example, silicon nitride (SiN).

A conductive layer 32 functioning as the control gate (backgate line BG) of the backgate transistor BT is formed on the insulating layer 31. Four conductive layers are formed on an insulating layer on the conductive layer 32, and function as the control gate (word line WL) of the memory cell transistor MT. A conductive layer is formed on an insulating layer on the uppermost word line, and functions as the gates (select gate lines SGD and SGS) of the select transistors ST1 and ST2. The U-shaped semiconductor layer 33 and the insulating layer 34 surrounding the semiconductor layer 33 are formed to extend through the backgate line, word lines WL, and select gate lines.

The line width and sectional area of the bit line BL decrease as the micropatterning of the memory cell array 20 advances. For example, the line width of the bit line BL is a minimum feature size F. An interconnect layer on the same level as that of the bit line BL will be represented by D1 hereinafter. An interconnect (D1 interconnect) included in interconnect layer D1 has almost the same sectional area as that of the bit line BL, and hence is a high-resistance interconnect.

Power lines PL, feed through lines FTL, and the like are formed above the bit line BL. An interconnect layer on the same level as that of the power line PL will be represented by D2 hereinafter. An interconnect (D2 interconnect) included in interconnect layer D2 has a line width and sectional area much larger than those of a D1 interconnect. Accordingly, a D2 interconnect is a low-resistance interconnect. That is, the wiring resistance of a D2 interconnect is much lower than that of a D1 interconnect.

### [1-2] Arrangement of Data Buses

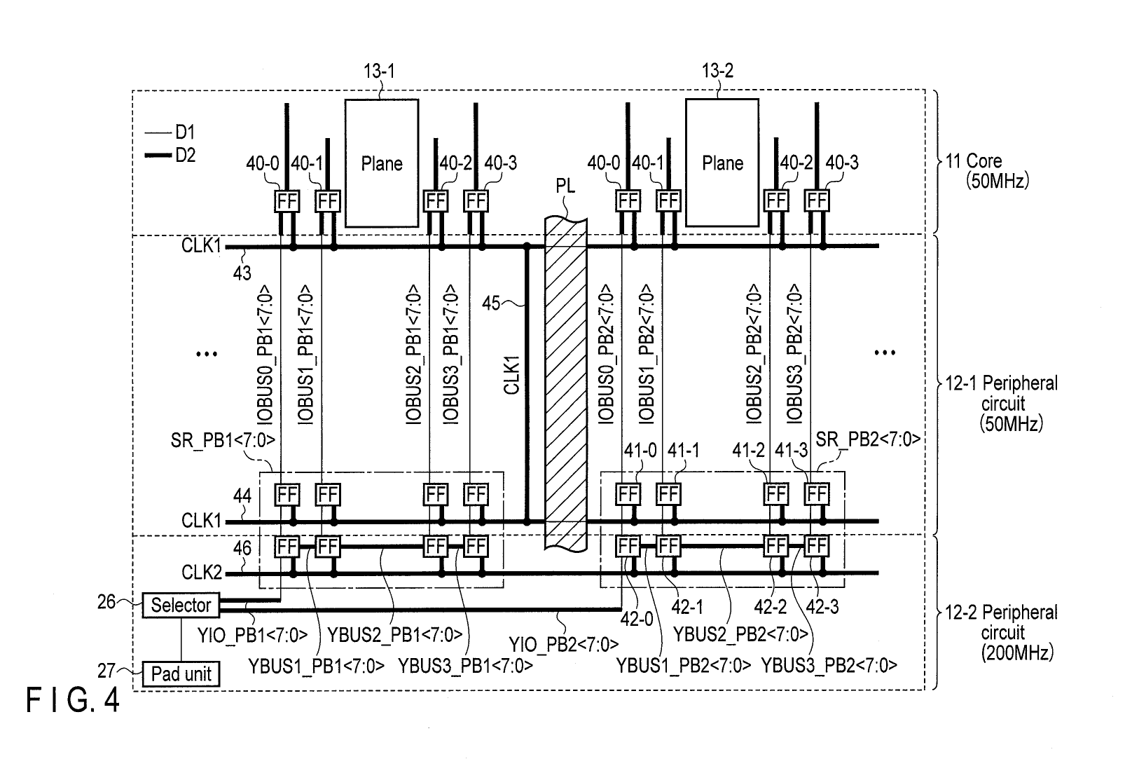

The arrangement of data buses of the NAND flash memory will now be explained. FIG. 4 is a view for explaining the arrangement of the data buses of the NAND flash memory. FIG. 4 specifically shows data buses for the planes 13-1 and 13-2. Also, in FIG. 4, thin lines indicate interconnects formed by interconnect layer D1 (i.e., high-resistance interconnects), and thick lines indicate interconnects formed by interconnect layer D2 (i.e., low-resistance interconnects). Although circuits of the plane 13-2 will be explained below as an example, the same shall apply to other planes 13. In this embodiment, the explanation will be made by assuming that data transfer is performed for every eight bits. However, the bit width can be freely set. In the entire embodiment, a connection of a data bus and a circuit includes manners in which (a) the data bus and the circuit are electrically connected, (b) the data bus and the circuit are physically connected, and (c) the data bus and the circuit are connected through an electric element (for example, a transistor).

The core 11 includes four flip-flops (FFs) 40-0 to 40-3 for holding data of the plane 13-2. Flip-flops 40-0 to 40-3 are respectively formed to correspond to units UT0 to UT3. Flip-flop 40-0 performs data transfer with unit UT0 in a memory cell array 20-2 via a sense amplifier 21A-2. Flip-flop 40-1 performs data transfer with unit UT1 via sense amplifier 21A-2. Flip-flop 40-2 performs data transfer with unit UT2 via a sense amplifier 21B-2. Flip-flop 40-3 performs data transfer with unit UT3 via sense amplifier 21B-2. Each of flip-flops 40-0 to 40-3 can hold eight bits at one time.

A shift register SR_PB2<7:0> includes flip-flops 41-0 to 41-3, and flip-flops 42-0 to 42-3. Each of flip-flops 41-0 to 41-3 can hold eight bits at one time. Likewise, each of flip-flops 42-0 to 42-3 can hold eight bits at one time.

Flip-flop 40-0 in the core 11 is connected to flip-flop 41-0 in shift register SR_PB2<7:0> via an 8-bit data bus IOBUS0_PB2<7:0>. Flip-flop 40-1 is connected to flip-flop 41-1 via a data bus IOBUS1_PB2<7:0>. Flip-flop 40-2 is connected to flip-flop 41-2 via a data bus IOBUS2_PB2<7:0>. Flip-flop 40-3 is connected to flip-flop 41-3 via a data bus IOBUS3_PB2<7:0>.

Flip-flops 41-0 to 41-3 are respectively connected to flip-flops 42-0 to 42-3 via 8-bit data buses. Flip-flops 42-0 to 42-3 are connected in series via 8-bit data buses, and configured to shift data. More specifically, flip-flops 42-0 and 42-1 are connected by a data bus YBUS1_PB2<7:0>. Flip-flops 42-1 and 42-2 are connected by a data bus YBUS2_PB2<7:0>. Flip-flops 42-2 and 42-3 are connected by a data bus YBUS3_PB2<7:0>. Flip-flop 42-0 is connected to the selector 26 via an 8-bit data bus YIO_PB2<7:0>.

Referring to FIG. 4, a low-operating-speed region of the peripheral circuit 12 shown in FIG. 1 will be represented by a peripheral circuit 12-1, and a high-operating-speed region of the peripheral circuit 12 will be represented by a peripheral circuit 12-2. The operating speed of peripheral circuit 12-1 is, for example, 50 MHz, and that of peripheral circuit 12-2 is, for example, 200 MHz. The operating speed of the core 11 is 50 MHz, i.e., the same as that of peripheral circuit 12-1.

Flip-flops 40-0 to 40-3 in the core 11 are formed near the boundary to peripheral circuit 12-1, and exchange data with peripheral circuit 12-1. Flip-flops 41-0 to 41-3 in peripheral circuit 12-1 are formed near the boundary to peripheral circuit 12-2, and exchange data with peripheral circuit 12-2. Flip-flops 42-0 to 42-3 in peripheral circuit 12-2 are formed near the boundary to peripheral circuit 12-1, and exchange data with peripheral circuit 12-1. The flip-flops are thus arranged near the boundaries of the areas.

Flip-flop 40-0 holds data of data bus IOBUS0_PB2<7:0> when inputting the data, and holds data read from unit UT0 when outputting the data. Flip-flops 40-1 to 40-3 are the same as flip-flop 40-0.

Flip-flop 41-0 holds data from flip-flop 42-0 when inputting the data, and holds data of data bus IOBUS0_PB2<7:0> when outputting the data. Flip-flops 41-1 to 41-3 are the same as flip-flop 41-0.

Flip-flop 42-0 holds data of data bus YIOPB2<7:0> when inputting the data, and holds data from flip-flop 41-0 when outputting the data. Flip-flops 42-1 to 42-3 are the same as flip-flop 42-0.

Flip-flops 40-0 to 40-3 and flip-flops 41-0 to 41-3 operate by a clock CLK1 having a frequency of 50 MHz. Flip-flops 42-0 to 42-3 operate by a clock CLK2 having a frequency of 200 MHz. An interconnect 43 for supplying clock CLK1 to flip-flops 40-0 to 40-3, an interconnect 44 for supplying clock CLK1 to flip-flops 41-0 to 41-3, and an interconnect 46 for supplying clock CLK2 to flip-flops 42-0 to 42-3 are formed by interconnect layer D2. Also, interconnects 43 and 44 are connected by an interconnect 45 formed adjacent to the power line PL. Like the power line PL, interconnect 45 is formed by interconnect layer D2. Note that those portions of interconnects 43 and 44 that intersect the power line PL are formed by interconnect layer D1 so as to be away from the power line PL.

Data buses IOBUS in peripheral circuit 12-1 are formed by interconnect layer D1. On the other hand, the data buses in the core 11 and peripheral circuit 12-2 are formed by interconnect layer D2. In other words, in the peripheral circuit 12 shown in FIG. 4, data buses running in the vertical direction of FIG. 4 are formed by interconnect layer D1, and data buses running in the horizontal direction of FIG. 4 are formed by interconnect layer D2.

### [1-3] Arrangement of Shift Register SR

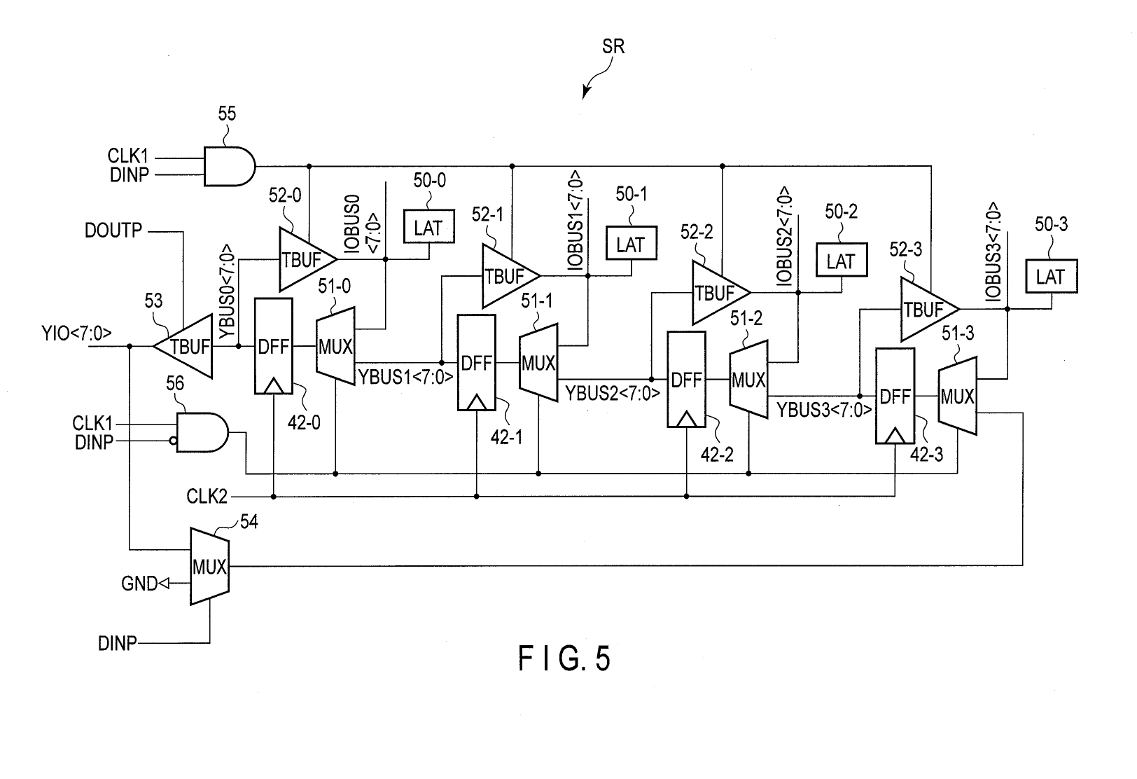

FIG. 5 is a circuit diagram showing an example of one shift register SR.

A data bus IOBUS0<7:0> is connected to a latch circuit (LAT) 50-0, the first input of a multiplexer (MUX) 51-0, and the output of a three-state buffer (TBUF) 52-0. The output of multiplexer 51-0 is connected to the input of the D flip-flop (DFF) 42-0. The output of flip-flop 42-0 is connected to a data bus YBUS0<7:0>. Flip-flop 42-0 holds an output from multiplexer 51-0 on the rising edge of clock CLK2.

Data bus YBUS0<7:0> is connected to the input of a three-state buffer 53, and the input of three-state buffer 52-0. The output of three-state buffer 53 is connected to a data bus YIO<7:0>. A signal DOUTP is input to the gate of three-state buffer 53. When signal DOUTP is high, three-state buffer 53 outputs data of data bus YBUS0<7:0>.

A circuit including latch circuit 50-0, multiplexer 51-0, and three-state buffer 52-0 corresponds to flip-flop 41-0 shown in FIG. 4. Circuit configurations concerning data buses IOBUS1 to IOBUS3 are the same as the above-described circuit configuration pertaining to data bus IOBUS0.

The output of flip-flop 42-1 is connected to the second input of multiplexer 51-0 via a data bus YBUS1<7:0>. The output of flip-flop 42-2 is connected to the second input of a multiplexer 51-1 via a data bus YBUS2<7:0>. The output of flip-flop 42-3 is connected to the second input of a multiplexer 51-2 via a data bus YBUS3<7:0>.

Data bus YIO<7:0> is connected to the first input of a multiplexer 54. The second input of multiplexer 54 is grounded (GND). A signal DINP is input to the gate of multiplexer 54. When signal DINP is high, multiplexer 54 outputs data of data bus YIO<7:0>.

An AND gate 55 has a first input to which clock CLK1 is input, and a second input to which signal DINP is input. The output of AND gate 55 is connected to the gates of three-state buffers 52-0 to 52-3.

An AND gate 56 has a first input to which clock CLK1 is input, and a second input (inverted input) to which signal DINP is input. The output of AND gate 56 is connected to the gates of multiplexers 51-0 to 51-3.

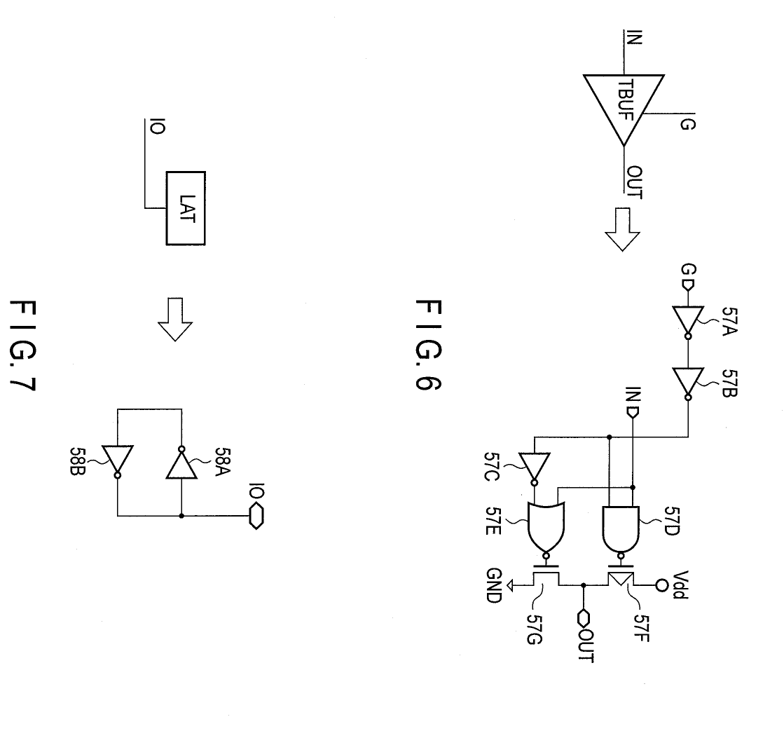

FIG. 6 is a circuit diagram showing an example of three-state buffer TBUF. A gate terminal G is connected to the input of an inverter 57A. The output of the inverter 57A is connected to the input of an inverter 57B.

An input terminal IN is connected to the first input of a NAND gate 57D, and the first input of a NOR gate 57E. The output of the inverter 57B is connected to the input of an inverter 57C, and the second input of the NAND gate 57D. The output of the inverter 57C is connected to the second input of the NOR gate 57E.

The output of the NAND gate 57D is connected to the gate of a P-channel MOSFET 57F. The output of the NOR gate 57E is connected to the gate of an N-channel MOSFET 57G. The source of the P-channel MOSFET 57F is connected to a power terminal Vdd. The drain of the P-channel MOSFET 57F is connected to an output terminal OUT, and the drain of the N-channel MOSFET 57G. The source of the N-channel MOSFET 57G is grounded.

FIG. 7 is a circuit diagram showing an example of latch circuit LAT. An input/output terminal 10 is connected to the input of an inverter 58A, and the output of an inverter 58B. The output of the inverter 58A is connected to the input of the inverter 58B.

### [2] Operation of NAND Flash Memory

Next, the operation of the NAND flash memory configured as described above will be explained.

The NAND flash memory of this embodiment is a three-dimensional stacked type memory, and the memory cell array 20 can be micropatterned. Accordingly, the capacitance of the bit line BL must be reduced in order to prevent the decrease in operating speed of the memory cell array 20. Therefore, the line width and sectional area of the bit line BL are decreased. In addition, the three-dimensional stacked type NAND flash memory requires a region for extracting a plurality of multilayered word lines WL and the like. This increases the size of the peripheral circuit 12, particularly, the length of the peripheral circuit 12 in the vertical direction of FIG. 4. For example, the length of the peripheral circuit 12 (peripheral circuits 12-1 and 12-2 in FIG. 4) is about 2,000 μm in the vertical direction.

As shown in FIG. 4, data buses IOBUS running in the vertical direction are formed by the same interconnect layer (high-resistance interconnect) D1 as that of the bit line BL, and hence cause a large wiring delay undesirable for the data buses. In this embodiment, therefore, the data buses of the peripheral circuit 12 are divided into a D1 interconnect region (peripheral circuit 12-1) and a D2 interconnect region (peripheral circuit 12-2). Since the long D1 interconnects are used in peripheral circuit 12-1 close to the core 11, the lengths of the data buses are increased, and the flip-flops are arranged near the circuit boundary, thereby operating the data buses parallel at 50 MHz, i.e., the same low speed as that of the core 11. On the other hand, in peripheral circuit 12-2 on the side of the pad unit 27, the D2 interconnects are used in most of the region, so the data buses are serially operated at a high speed of 200 MHz.

### [2-1] Data Input Operation

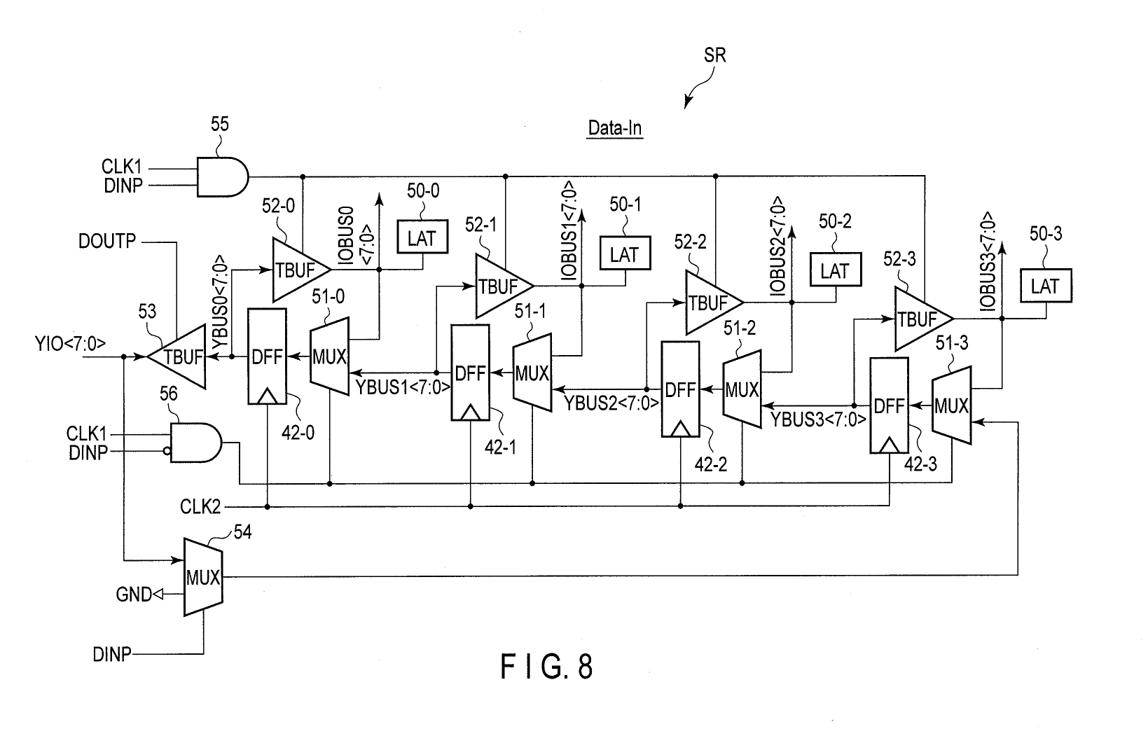

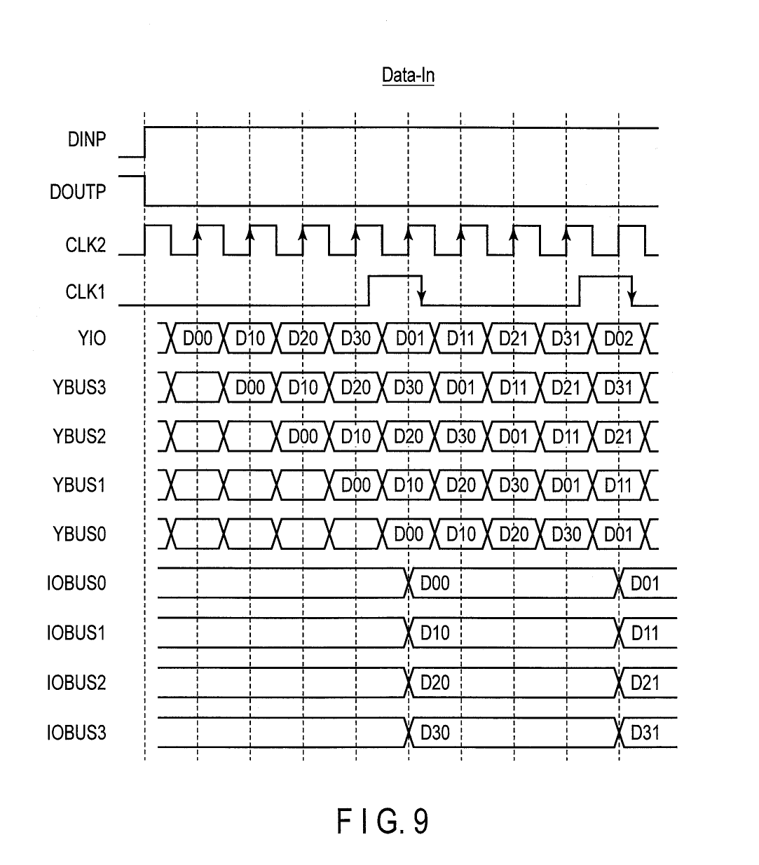

FIG. 8 is a view for explaining data flows in the shift register SR when inputting data. Arrows in FIG. 8 indicate the data flows. FIG. 9 is a timing chart showing the data input operation of the NAND flash memory. As described earlier, the frequency of clock CLK1 is, for example, 50 MHz, and that of clock CLK2 is, for example, 200 MHz.

First, data is serially input every eight bits from an external circuit to the pad unit 27. The selector 26 sequentially supplies the input data to data bus YIO<7:0> corresponding to a plane (called a selected plane) as a data input target.

When inputting data, signal DINP goes high. Flip-flop 42-3 holds input data D00 input via multiplexers 54 and 51-3 on the rising edge of clock CLK2. On the next rising edge of clock CLK2, flip-flop 42-2 holds input data D00 input via data bus YBUS3<7:0> and multiplexer 51-2, and flip-flop 42-3 holds input data D10 following input data D00. By repeating this operation, input data D00 to D30 are shifted in flip-flops 42-3 to 42-0, and flip-flops 42-0 to 42-3 respectively hold input data D00 to D30.

Subsequently, flip-flops 41-0 to 41-3 respectively hold input data D00 to D30 on the falling edge of clock CLK1. Input data D00 to D30 held in flip-flops 41-0 to 41-3 are respectively transferred to flip-flops 40-0 to 40-3 in the core 11 via data buses IOBUS0<7:0> to IOBUS3<7:0>. At this point of time, the operation of transferring input data D00 to D30 in the peripheral circuit 12 is completed.

After that, sense amplifiers 21A and 21B write input data D00 to D30 to the memory cell array 20 in the selected plane 13. The same operation as that described above is repetitively performed on input data D01 to D31 following input data D00 to D30.

By this data input operation, the data transfer rate can be converted from 200 to 50 MHz in the boundary between peripheral circuits 12-1 and 12-2. Also, in peripheral circuit 12-1 using the long D1 interconnects as the data buses, the data buses can be operated parallel at a low speed of 50 MHz, so data transfer can accurately be performed even when a wiring delay increases.

### [2-2] Data Output Operation

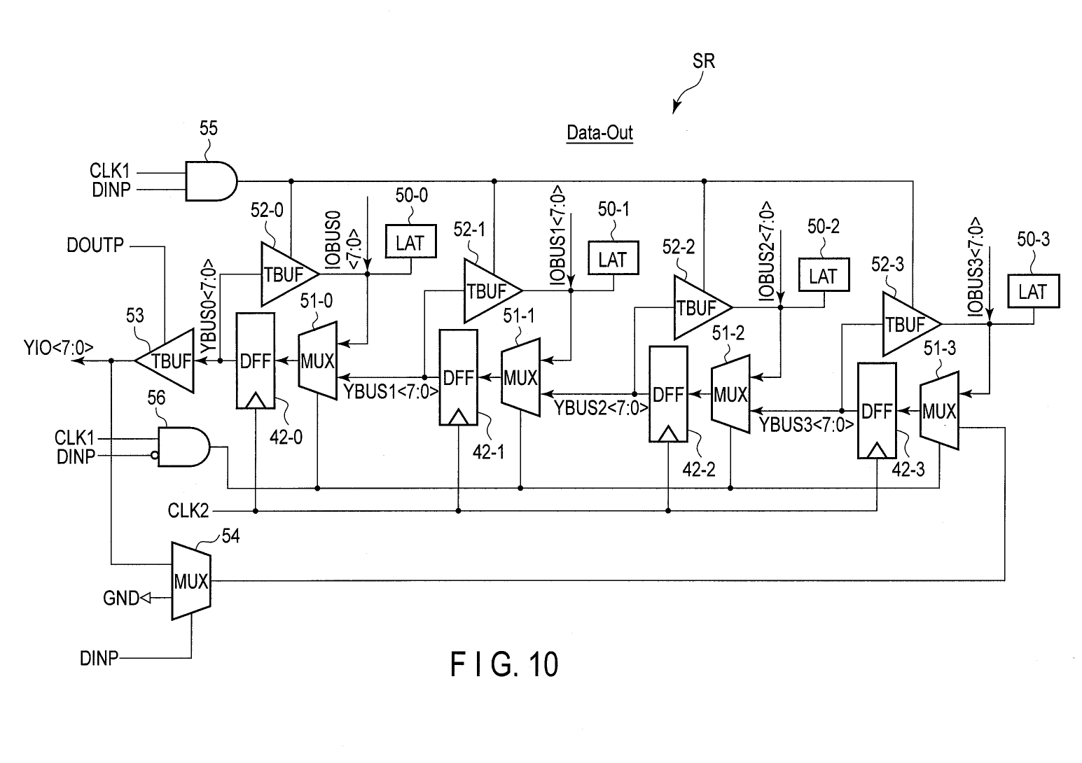

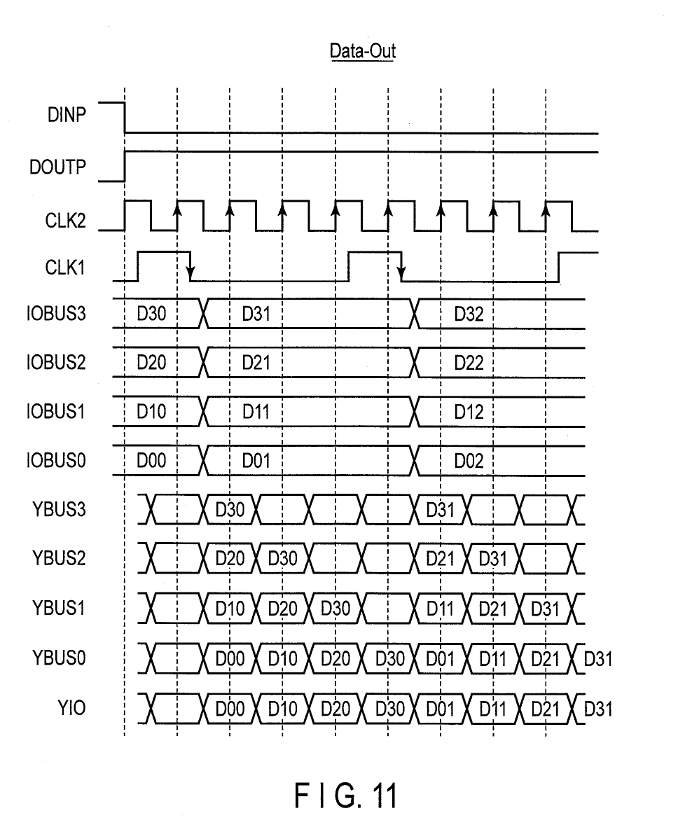

FIG. 10 is a view for explaining data flows in the shift register SR when outputting data. Arrows in FIG. 10 indicate the data flows. FIG. 11 is a timing chart showing the data output operation of the NAND flash memory.

First, a read operation is executed in a plane (called a selected plane) as a data output target, and output data read from the selected plane 13 is held in flip-flops 40-0 to 40-3 in the core 11. When outputting data, signal DOUTP goes high.

Then, output data D00 to D30 respectively held in flip-flops 40-0 to 40-3 are transferred to data buses IOBUS0<7:0> to IOBUS3<7:0>. Flip-flops 41-0 to 41-3 respectively hold output data D00 to D30 on the falling edge of clock CLK1.

Subsequently, flip-flops 42-0 to 42-3 respectively hold output data D00 to D30 input via multiplexers 51-0 to 51-3 on the rising edge of clock CLK2. At this time, output data D00 held in flip-flop 42-0 is output to data bus YIO<7:0> via data bus YBUS0<7:0> and three-state buffer 53.

On the next rising edge of clock CLK2, flip-flop 42-0 holds output data D10 input via data bus YBUS1<7:0> and multiplexer 51-0, and flip-flop 42-1 holds output data D20 following output data D10. By repeating this operation, output data D00 to D30 are shifted in flip-flops 42-0 to 42-3. Consequently, flip-flop 42-0 serially transfers output data D00 to D30 to data bus YIO<7:0>.

The selector 26 selects the output data transferred to YIO<7:0>. The selector 26 outputs the data to an external circuit via the pad unit 27. The same operation is repetitively performed on output data D01 to D31 following output data D00 to D30.

By this data output operation, the data transfer rate can be converted from 50 to 200 MHz in the boundary between peripheral circuits 12-1 and 12-2. Also, in peripheral circuit 12-1 using the long D1 interconnects as the data buses, the data buses can be operated parallel at a low speed of 50 MHz, so data transfer can accurately be performed even when a wiring delay increases.

### [3] Effects

In the first embodiment as has been explained in detail above, the peripheral circuit 12 for transferring data between the core (memory core) 11 and pad unit 27 is divided into the first region (peripheral circuit 12-1) in which data buses formed by the D1 interconnects (high-resistance interconnects) are formed, and the second region (peripheral circuit 12-2) in which data buses formed by the D2 interconnects (low-resistance interconnects) are formed. The data buses in peripheral circuit 12-1 transfer data at a first operating speed (for example, 50 MHz), whereas the data buses in peripheral circuit 12-2 transfer data at a second operating speed (for example, 200 MHz) higher than the first operating speed.

Accordingly, the first embodiment can easily and more accurately increase the speed of the data buses as a whole in the peripheral circuit 12. It is also possible to implement first-in first-out (FIFO) data transfer at high speed.

Furthermore, in peripheral circuit 12-1 using the high-resistance interconnects, data transfer is performed parallel at 50 MHz, i.e., the same operating speed as that of the core 11, so the data transfer operation can accurately and reliably performed. In peripheral circuit 12-2, a high-speed operation can be performed because data transfer is serially performed at an operating speed of 200 MHz. In addition, the arrangement of the first embodiment is flexibly changeable by the floor plan of the peripheral circuit 12 or the interconnect manufacturing process.

Also, the shift register SR is formed in the boundary between peripheral circuits 12-1 and 12-2, and the operating speed is converted by using the flip-flops included in the shift register SR. This makes it possible to accurately convert the operating speed in the boundary between peripheral circuits 12-1 and 12-2.

Moreover, the arrangement of this embodiment does not require many drivers in order to ensure a high-speed operation. Therefore, it is possible to assure an accurate high-speed operation while reducing the cost without complicating the circuit configuration.

### Second Embodiment

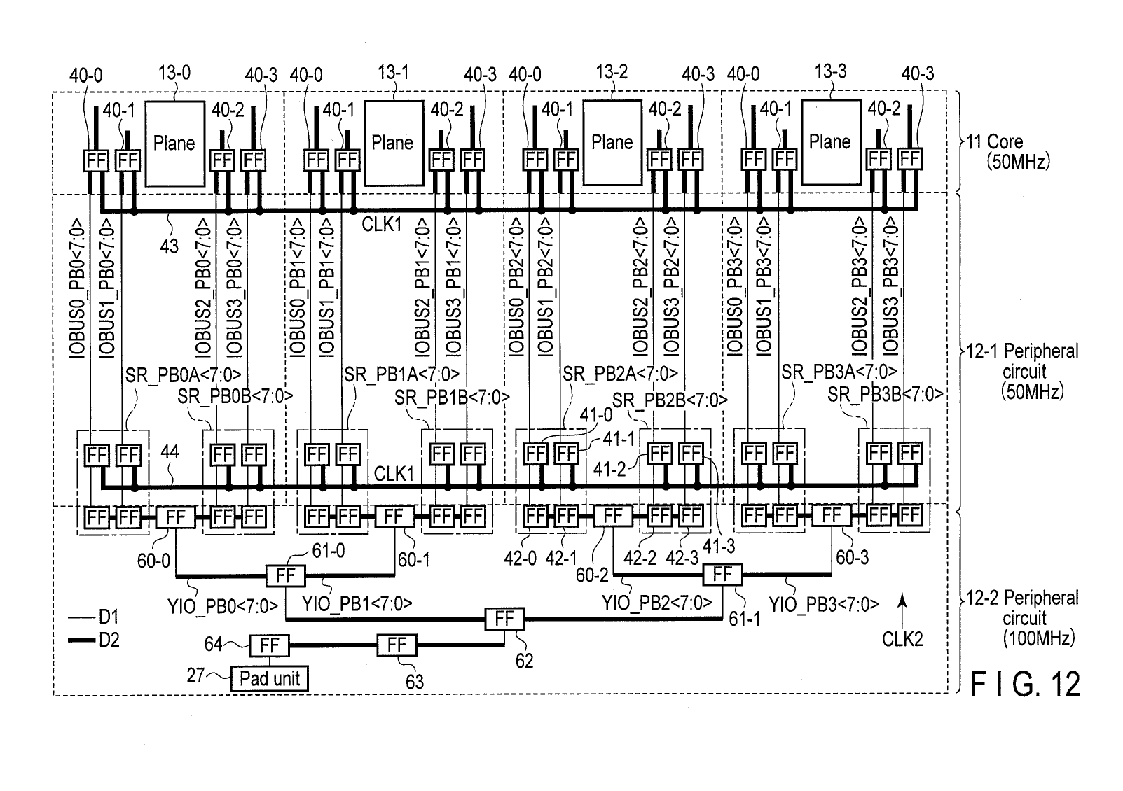

In the second embodiment, data buses are divided into a low-speed region and high-speed region as in the first embodiment, but a tree structure is used as the data buses in order to eliminate data transfer variations between planes. FIG. 12 is a view for explaining the arrangement of the data buses of a NAND flash memory according to the second embodiment.

The following explanation will be made by taking the arrangement of a shift register SR for a plane 13-2 as an example, but the same explanation applies to other planes 13. In this embodiment, data transfer is performed for, for example, every eight bits.

A shift register SR_PB2A<7:0> includes flip-flops 41-0 and 41-1 and flip-flops 42-0 and 42-1. Each of flip-flops 41-0 and 41-1 and flip-flops 42-0 and 42-1 can hold eight bits at one time.

Flip-flop 41-0 is connected to a data bus IOBUS0_PB2<7:0>. Flip-flop 41-1 is connected to a data bus IOBUS1_PB2<7:0>. Flip-flops 41-0 and 41-1 are respectively connected to flip-flops 42-0 and 42-1 via 8-bit data buses. Flip-flops 42-0 and 42-1 are connected in series. Flip-flops 42-0 and 42-1 are configured to shift data.

A shift register SR_PB2B<7:0> includes flip-flops 41-2 and 41-3 and flip-flops 42-2 and 42-3. Each of flip-flops 41-2 and 41-3 and flip-flops 42-2 and 42-3 can hold eight bits at one time.

Flip-flop 41-2 is connected to a data bus IOBUS2_PB2<7:0>. Flip-flop 41-3 is connected to a data bus IOBUS3_PB2<7:0>. Flip-flops 41-2 and 41-3 are respectively connected to flip-flops 42-2 and 42-3 via 8-bit data buses. Flip-flops 42-2 and 42-3 are connected in series. Flip-flops 42-2 and 42-3 are configured to shift data.

Shift registers SR_PB2A<7:0> and SR_PB2B<7:0> can have the same arrangement as that of the shift register explained with reference to FIG. 5 in the first embodiment.

Flip-flops 42-1 and 42-2 are connected to a flip-flop 60-2. Flip-flop 60-2 for the plane 13-2 is connected to a flip-flop 61-1 via a data bus YIO_PB2<7:0>. A flip-flop 60-3 for a plane 13-3 is connected to flip-flop 61-1 via a data bus YIO_PB3<7:0>. A flip-flop 60-0 for a plane 13-0 is connected to a flip-flop 61-0 via a data bus YIO_PB0<7:0>. A flip-flop 60-1 for a plane 13-1 is connected to flip-flop 61-0 via a data bus YIO_PB1<7:0>.

Flip-flops 61-0 and 61-1 are connected to a flip-flop 62 via data buses. Flip-flop 62 is connected to a pad unit 27 via flip-flops 63 and 64.

Data buses IOBUS in a peripheral circuit 12-1 are formed by an interconnect layer D1 (i.e., high-resistance interconnects). On the other hand, data buses in a core 11 and peripheral circuit 12-2 are formed by an interconnect layer D2 (i.e., low-resistance interconnects). In other words, in a peripheral circuit 12 shown in FIG. 12, data buses running in the vertical direction of FIG. 12 are formed by interconnect layer D1, and data buses running in the horizontal direction of FIG. 12 are formed by interconnect layer D2. Referring to FIG. 12, thin lines indicate the interconnects formed by interconnect layer D1, and thick lines indicate the interconnects formed by interconnect layer D2.

The frequency of a clock CLK1 is, for example, 50 MHz, and that of a clock CLK2 is, for example, 100 MHz. Note that clock CLK2 is supplied to all flip-flops in peripheral circuit 12-2, but interconnects for clock CLK2 are omitted from FIG. 12 in order to avoid the complexity of the drawing.

Next, the operation of the NAND flash memory configured as described above will be explained. In a data input operation, the pad unit 27 performs a DDR (Double Data Rate) operation, thereby converting the data transfer rate from 200 to 100 MHz. Also, the data transfer rate is converted from 100 to 50 MHz in the boundary between peripheral circuits 12-2 and 12-1. In peripheral circuit 12-1 using the long D1 interconnects as the data buses, an operation can be performed at a low speed of 50 MHz, so accurate data transfer can be performed even when a wiring delay increases.

In a data output operation, the data transfer rate is converted from 50 to 100 MHz in the boundary between peripheral circuits 12-1 and 12-2. In addition, the data transfer rate is converted from 100 to 200 MHz by performing the DDR operation in the pad unit 27. In peripheral circuit 12-1 using the long D1 interconnects as the data buses, an operation can be performed at a low speed of 50 MHz, so accurate data transfer can be performed even when a wiring delay increases.

In the second embodiment as has been explained in detail above, as shown in FIG. 12, the data buses extending from the pad unit 27 toward peripheral circuit 12-1 sequentially branch in peripheral circuit 12-2. That is, the data buses of peripheral circuit 12-2 have a tree structure. Accordingly, the interconnect lengths between the planes 13 can be made almost the same for the data buses in the peripheral circuit 12. This makes it possible to reduce variations in transfer rate between the planes 13. The rest of the effects are the same as those of the first embodiment.

### Third Embodiment

In the third embodiment, some data buses are arranged below a memory cell array. In addition, the data buses below the memory cell array are operated at low speed, and data buses near a pad unit are operated at high speed, thereby increasing the speed of the data buses as a whole.

### [1] Arrangement of Data Buses

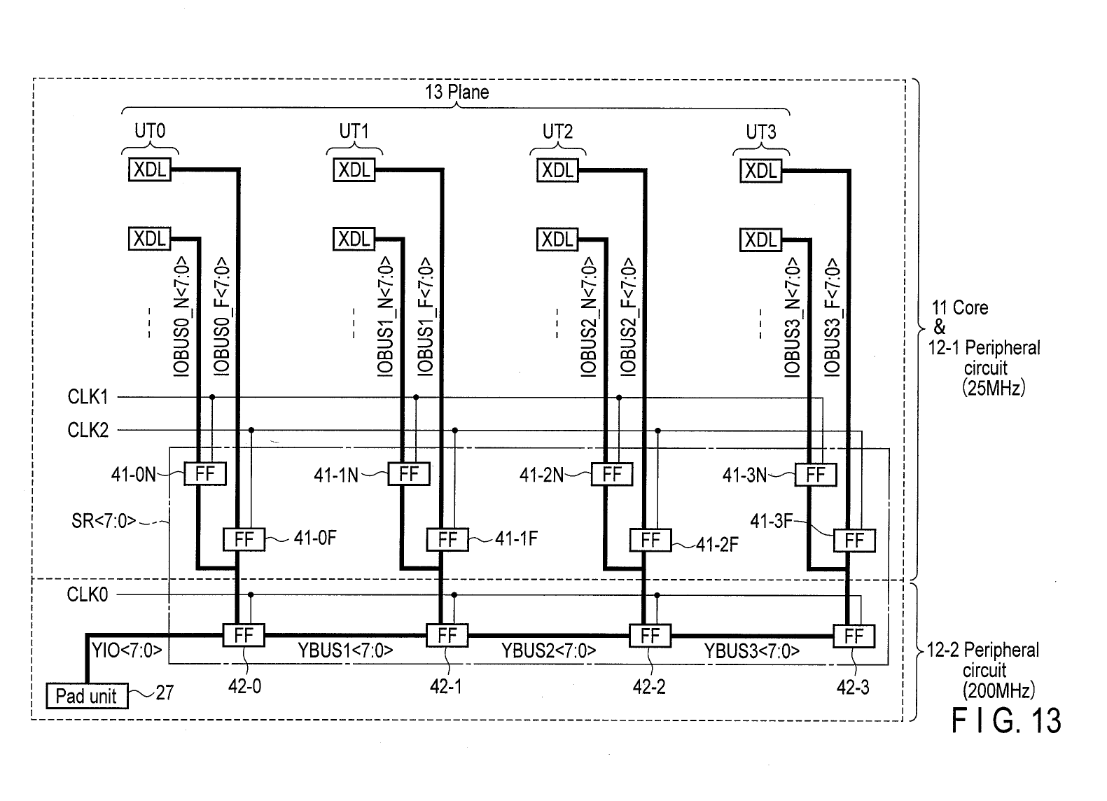

FIG. 13 is a view for explaining the arrangement of data buses of a NAND flash memory according to the third embodiment. FIG. 13 specifically shows data buses corresponding to one plane 13. The arrangement of data buses for other planes is the same as that shown in FIG. 13. This embodiment will be explained by assuming that data transfer is performed for, for example, every eight bits, but the bit width can be freely set.

FIG. 13 specifically shows data latches XDL as circuits included in a core 11. The plane 13 includes the data latches XDL that temporarily hold data read from a memory cell array 20, and temporarily hold data to be written to the memory cell array 20. The data latches XDL are included in a sense amplifier 21. One data latch XDL shown in FIG. 13 can hold eight bits at one time.

A first data latch XDL connected to a unit UT0 is connected to a flip-flop 41-0N in a shift register SR<7:0> via an 8-bit data bus IOBUS0_N<7:0>. A second data latch XDL connected to unit UT0 is connected to a flip-flop 41-0F in the shift register SR<7:0> via an 8-bit data bus IOBUS0_F<7:0>. Although operations concerning the two data buses (IOBUS0_N<7:0> and IOBUS0_F<7:0>) connected to unit UT0 will be explained below, more data buses are actually connected to unit UT0. The same shall apply to other units.

A first data latch XDL connected to a unit UT1 is connected to a flip-flop 41-1N in the shift register SR<7:0> via an 8-bit data bus IOBUS1_N<7:0>. A second data latch XDL connected to unit UT1 is connected to a flip-flop 41-1F in the shift register SR<7:0> via an 8-bit data bus IOBUS1_F<7:0>. Likewise, flip-flops 41-2N and 41-2F are respectively connected to a unit UT2 via data buses IOBUS2_N<7:0> and IOBUS2_F<7:0>. Also, flip-flops 41-3N and 41-3F are respectively connected to a unit UT3 via data buses IOBUS3_N<7:0> and IOBUS3_F<7:0>.

Flip-flops 41-0N and 41-0F are connected to a flip-flop 42-0 via 8-bit data buses. Flip-flops 41-1N and 41-1F are connected to a flip-flop 42-1 via 8-bit data buses. Flip-flops 41-2N and 41-2F are connected to a flip-flop 42-2 via 8-bit data buses. Flip-flops 41-3N and 41-3F are connected to a flip-flop 42-3 via 8-bit data buses.

Flip-flops 42-0 to 42-3 are connected in series via 8-bit data buses, and thus configured to shift data. More specifically, flip-flops 42-0 and 42-1 are connected by a data bus YBUS1<7:0>. Flip-flops 42-1 and 42-2 are connected by a data bus YBUS2<7:0>. Flip-flops 42-2 and 42-3 are connected by a data bus YBUS3<7:0>. Flip-flop 42-0 is connected to a pad unit 27 via an 8-bit data bus YIO<7:0>.

Flip-flops 41-0N to 41-3N operate with a clock CLK1. Flip-flops 41-0F to 41-3F operate with a clock CLK2. Flip-flops 42-0 to 42-3 operate with a clock CLK0. The frequency of clock CLK0 is, for example, 200 MHz. The frequencies of clocks CLK1 and CLK2 are, for example, 25 MHz, and have different phases. That is, the operating speed of a peripheral circuit 12-1 (including data buses IOBUS0 to IOBUS3, and some data buses and some flip-flop included in the shift register SR) is, for example, 25 MHz, and that of a peripheral circuit 12-2 (including some data buses and some flip-flop included in the shift register SR) is, for example, 200 MHz. The operating speed of the core 11 is 25 MHz, i.e., the same as that of peripheral circuit 12-1.

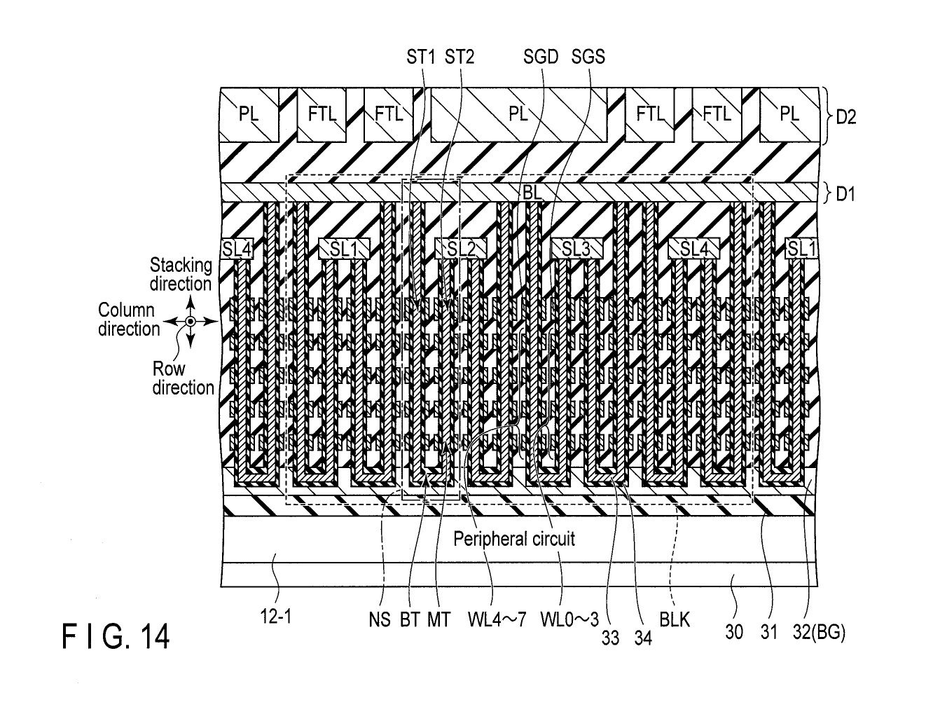

In this embodiment, peripheral circuit 12-1 is embedded below the memory cell array as shown in FIG. 14, and operated parallel at low speed (25 MHz). On the other hand, peripheral circuit 12-2 is positioned near the pad unit 27 outside the memory cell array, and serially operated at high speed (200 MHz). This makes it possible to increase the speed of the data buses as a whole, reduce the power consumption of the data buses, and reduce the circuit area of the NAND flash memory.

### [2] Arrangement of Shift Register SR

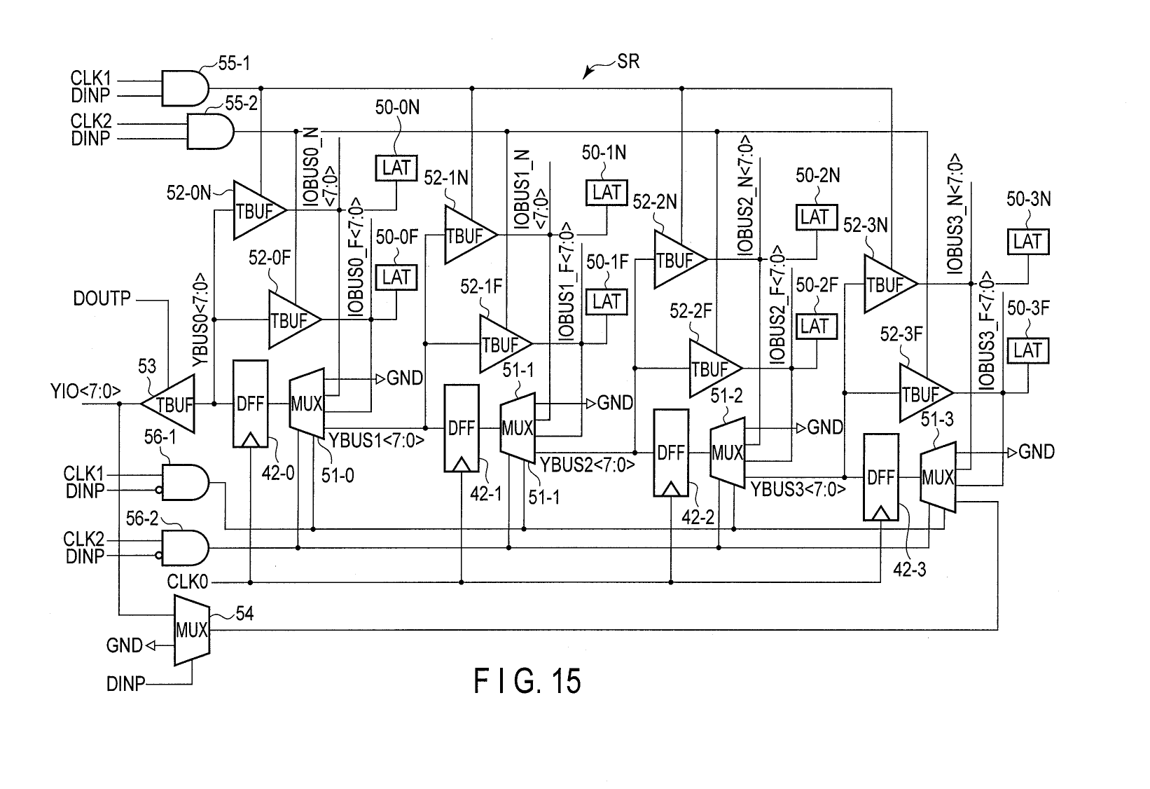

FIG. 15 is a circuit diagram showing an example of the shift register SR.

Data bus IOBUS0_N<7:0> is connected to a latch circuit (LAT) 50-0N, the second input of a multiplexer (MUX) 51-0, and the output of a three-state buffer (TBUF) 52-0N. The first input of multiplexer 51-0 is grounded. Data bus IOBUS0_F<7:0> is connected to a latch circuit 50-0F, the third input of multiplexer 51-0, and the output of a three-state buffer 52-0F. The output of multiplexer 51-0 is connected to the input of the D flip-flop (DFF) 42-0. The output of flip-flop 42-0 is connected to a data bus YBUS0<7:0>. Flip-flop 42-0 holds an output from multiplexer 51-0 on the rising edge of clock CLK0. Data bus YBUS0<7:0> is connected to the inputs of three-state buffers 53, 52-0N, and 52-0F.

A circuit including latch circuit 50-0N, multiplexer 51-0, and three-state buffer 52-0N corresponds to flip-flop 41-0N shown in FIG. 13. A circuit including latch circuit 50-0F, multiplexer 51-0, and three-state buffer 52-0F corresponds to flip-flop 41-0F shown in FIG. 13. Circuit configurations concerning data buses IOBUS1 to IOBUS3 are the same as the above-described circuit configuration pertaining to data bus IOBUS0.

The output of flip-flop 42-1 is connected to the fourth input of multiplexer 51-0 via data bus YBUS1<7:0>. The output of flip-flop 42-2 is connected to the fourth input of multiplexer 51-1 via data bus YBUS2<7:0>. The output of flip-flop 42-3 is connected to the fourth input of multiplexer 51-2 via data bus YBUS3<7:0>.

An AND gate 55-1 has a first input to which clock CLK1 is input, and a second input to which a signal DINP is input. The output of AND gate 55-1 is connected to the gates of three-state buffers 52-0N to 52-3N. An AND gate 55-2 has a first input to which clock CLK2 is input, and a second input to which signal DINP is input. The output of AND gate 55-2 is connected to the gates of three-state buffers 52-0F to 52-3F.

An AND gate 56-1 has a first input to which clock CLK1 is input, and a second input (inverted input) to which signal DINP is input. The output of AND gate 56-1 is connected to the first gates of multiplexers 51-0 to 51-3. An AND gate 56-2 has a first input to which clock CLK2 is input, and a second input (inverted input) to which signal DINP is input. The output of AND gate 56-2 is connected to the second gates of multiplexers 51-0 to 51-3.

### [3] Operation of NAND Flash Memory

The operation of the NAND flash memory configured as described above will be explained below.

### [3-1] Data Input Operation

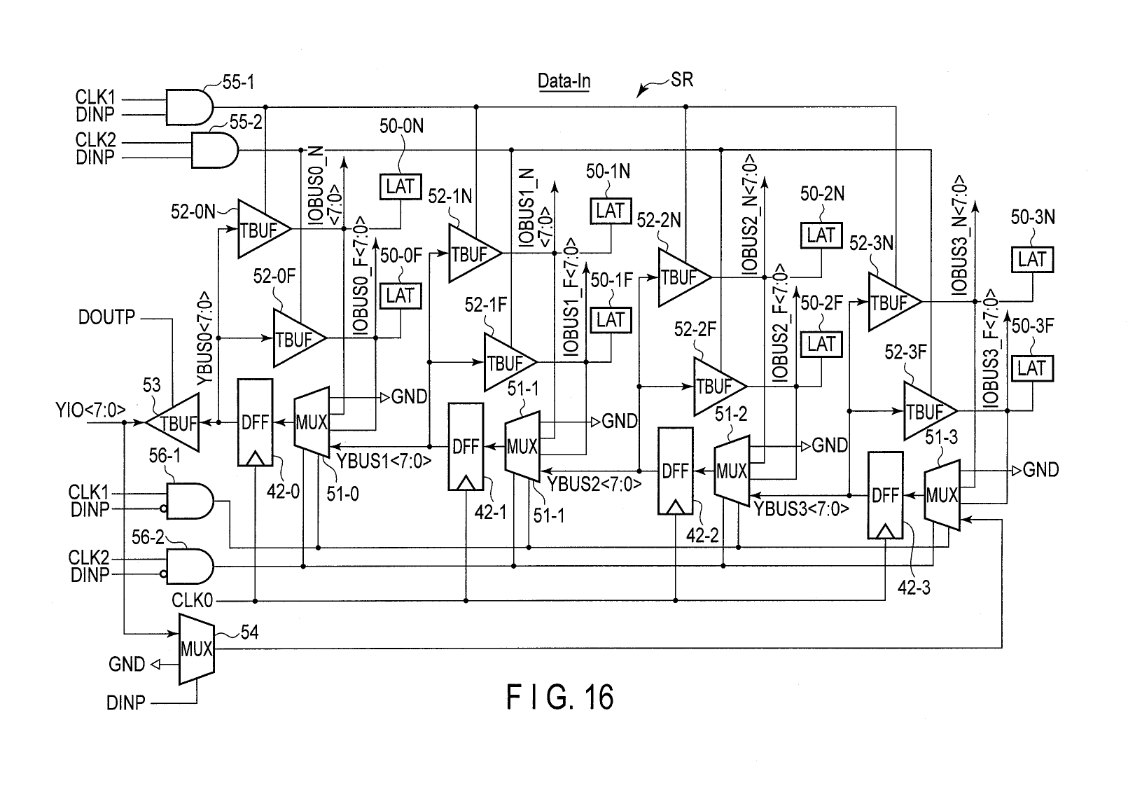

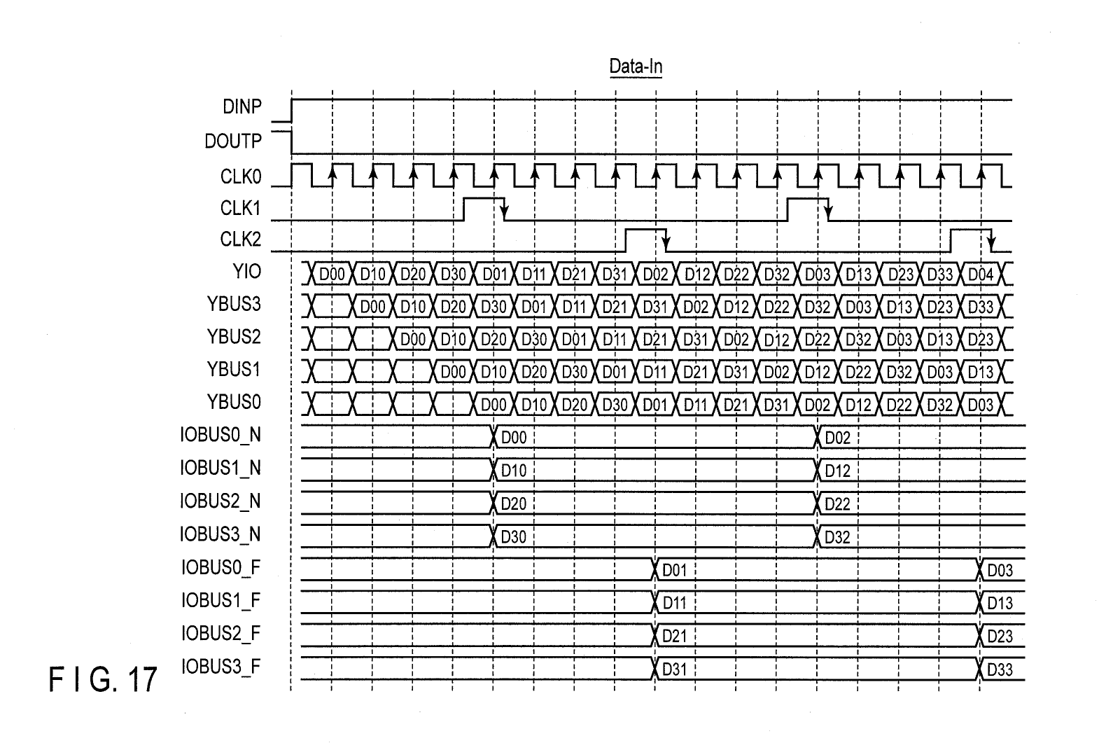

FIG. 16 is a view for explaining data flows in the shift register SR when inputting data. Arrows in FIG. 16 indicate the data flows. FIG. 17 is a timing chart showing the data input operation of the NAND flash memory. As described earlier, the frequency of clock CLK0 is, for example, 200 MHz, and the frequencies of clocks CLK1 and CLK2 are, for example, 25 MHz and have different phases.

First, data is serially input every eight bits from an external circuit to the pad unit 27. When inputting data, signal DINP goes high. Flip-flop 42-3 holds input data D00 input via multiplexers 54 and 51-3 on the rising edge of clock CLK0. On the next rising edge of clock CLK0, flip-flop 42-2 holds input data D00 input via data bus YBUS3<7:0> and multiplexer 51-2, and flip-flop 42-3 holds input data D10 following input data D00. By repeating this operation, input data D00 to D30 are shifted in flip-flops 42-3 to 42-0, and flip-flops 42-0 to 42-3 respectively hold input data D00 to D30.

Subsequently, flip-flops 41-0N to 41-3N respectively hold input data D00 to D30 on the falling edge of clock CLK1. Input data D00 to D30 held in flip-flops 41-0N to 41-3N are respectively transferred to the plane 13 via data buses IOBUS0_N<7:0> to IOBUS3_N<7:0>.

Similarly, after input data D01 to D31 are respectively held in flip-flops 42-0 to 42-3, flip-flops 41-0F to 41-3F respectively hold input data D01 to D31 on the falling edge of clock CLK2. Input data D01 to D31 held in flip-flops 41-0F to 41-3F are respectively transferred to the plane 13 via data buses IOBUS0_F<7:0> to IOBUS3_F<7:0>.

By this data input operation, the data transfer rate can be converted from 200 to 25 MHz in the boundary between peripheral circuits 12-1 and 12-2. Also, in peripheral circuit 12-1, the data buses can be operated parallel at a low speed of 25 MHz, so data transfer can accurately be performed even when a wiring delay increases.

### [3-2] Data Output Operation

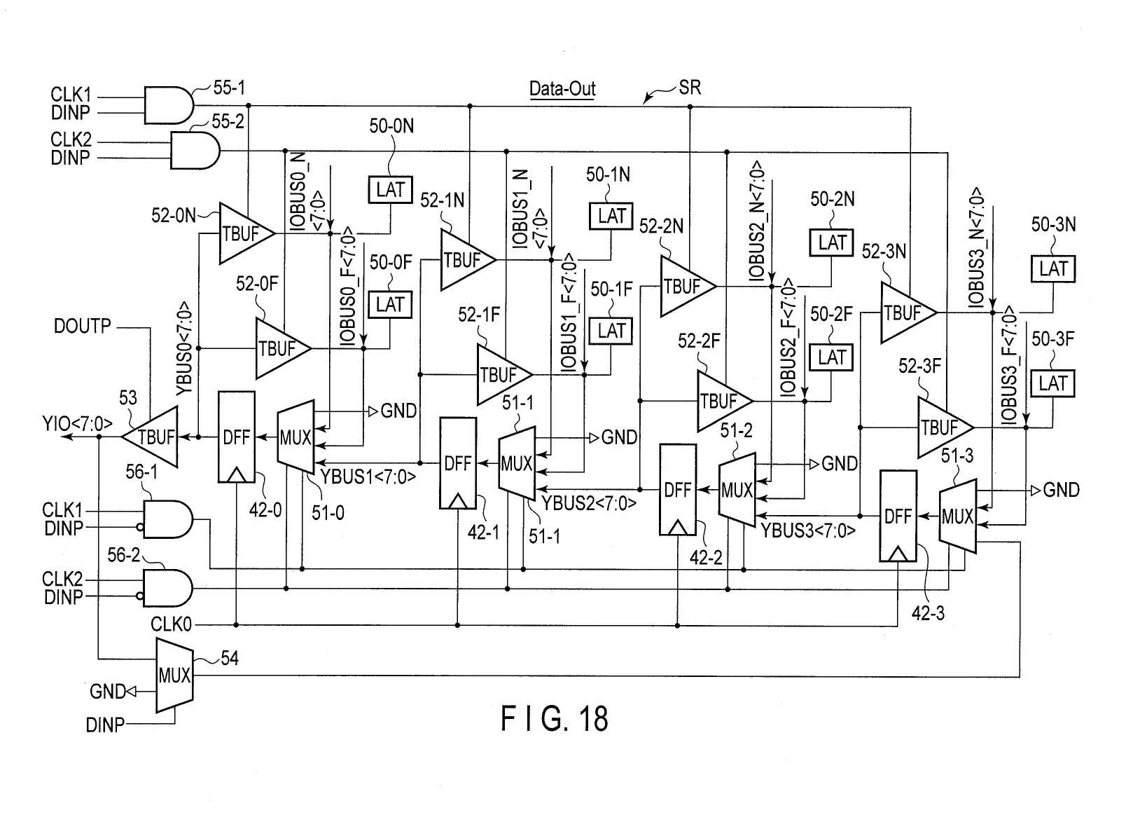

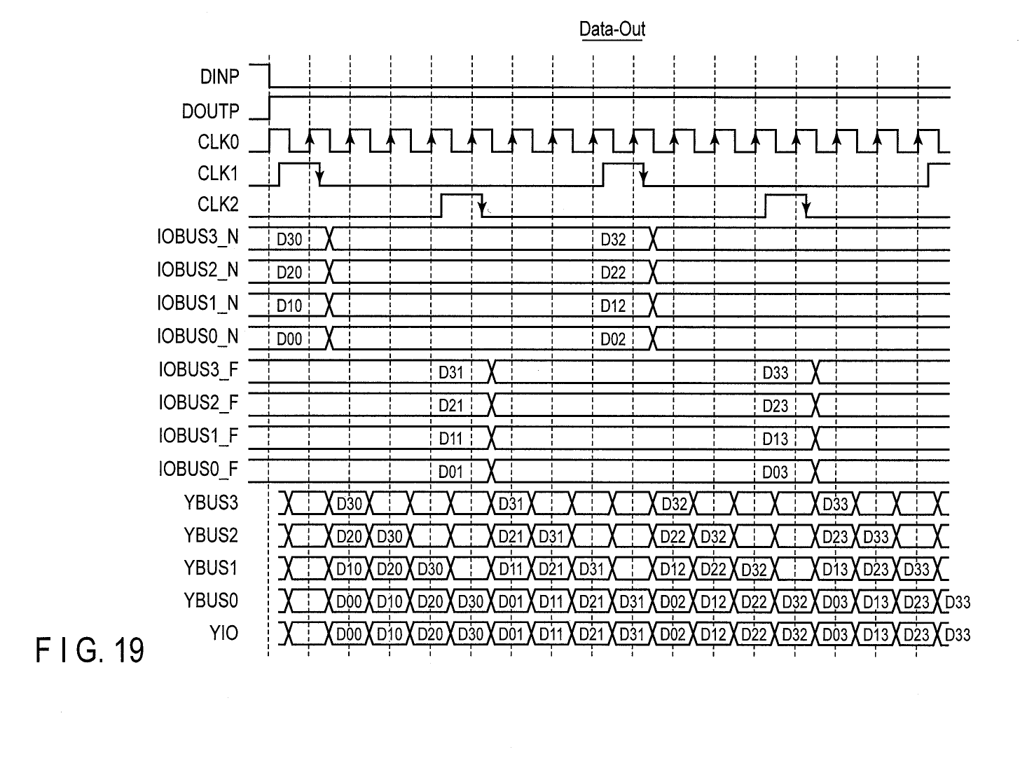

FIG. 18 is a view for explaining data flows in the shift register SR when outputting data. Arrows in FIG. 18 indicate the data flows. FIG. 19 is a timing chart showing the data output operation of the NAND flash memory.

First, a read operation is executed in the plane 13, and output data D00 to D30 read from the plane 13 are respectively transferred to data buses IOBUS0_N<7:0> to IOBUS3_N<7:0>. When outputting data, signal DOUTP goes high. Then, flip-flops 41-0N to 41-3N respectively hold output data D00 to D30 on the falling edge of clock CLK1.

Subsequently, flip-flops 42-0 to 42-3 respectively hold output data D00 to D30 input via multiplexers 51-0 to 51-3 on the rising edge of clock CLK0. At this time, output data D00 held in flip-flop 42-0 is output to data bus YIO<7:0> via data bus YBUS0<7:0> and three-state buffer 53.

On the next rising edge of clock CLK0, flip-flop 42-0 holds output data D10 input via data bus YBUS1<7:0> and multiplexer 51-0, and flip-flop 42-1 holds output data D20 following output data D10. By repeating this operation, output data D00 to D30 are shifted in flip-flops 42-0 to 42-3. Consequently, flip-flop 42-0 serially transfers output data D00 to D30 to data bus YIO<7:0>.

Analogously, after output data D01 to D31 are transferred to data buses IOBUS0_F<7:0> to IOBUS3_F<7:0>, flip-flops 41-0F to 41-3F respectively hold output data D01 to D31 on the falling edge of clock CLK2. Flip-flops 42-0 to 42-3 respectively hold output data D01 to D31 input via multiplexers 51-0 to 51-3 on the rising edge of clock CLK0. After that, flip-flops 42-0 to 42-3 shift output data D01 to D31, and flip-flop 42-0 serially transfers output data D01 to D31 to data bus YIO<7:0>.

By this data output operation, the data transfer rate can be converted from 25 to 200 MHz in the boundary between peripheral circuits 12-1 and 12-2. Also, in peripheral circuit 12-1, the data buses can be operated parallel at a low speed of 25 MHz, so data transfer can accurately be performed even when a wiring delay increases.

### [4] Effects

As has been explained in detail above, the third embodiment can easily and more accurately increase the speed of the data buses as a whole in the peripheral circuit 12. It is also possible to implement first-in first-out (FIFO) data transfer at high speed. Furthermore, in peripheral circuit 12-1, data transfer is performed parallel at an operating speed of 25 MHz, so the data transfer operation can accurately and reliably performed. In peripheral circuit 12-2, a high-speed operation can be performed because data transfer is serially performed at an operating speed of 200 MHz.

In addition, peripheral circuit 12-1 is embedded below the memory cell array. Even when the data buses of this embodiment are implemented, therefore, the circuit area of the NAND flash memory can be reduced. Also, the power consumption of data transfer can further be reduced by further decreasing the data bus operating speed in peripheral circuit 12-1 from 50 to 25 MHz.

### Comparative Example

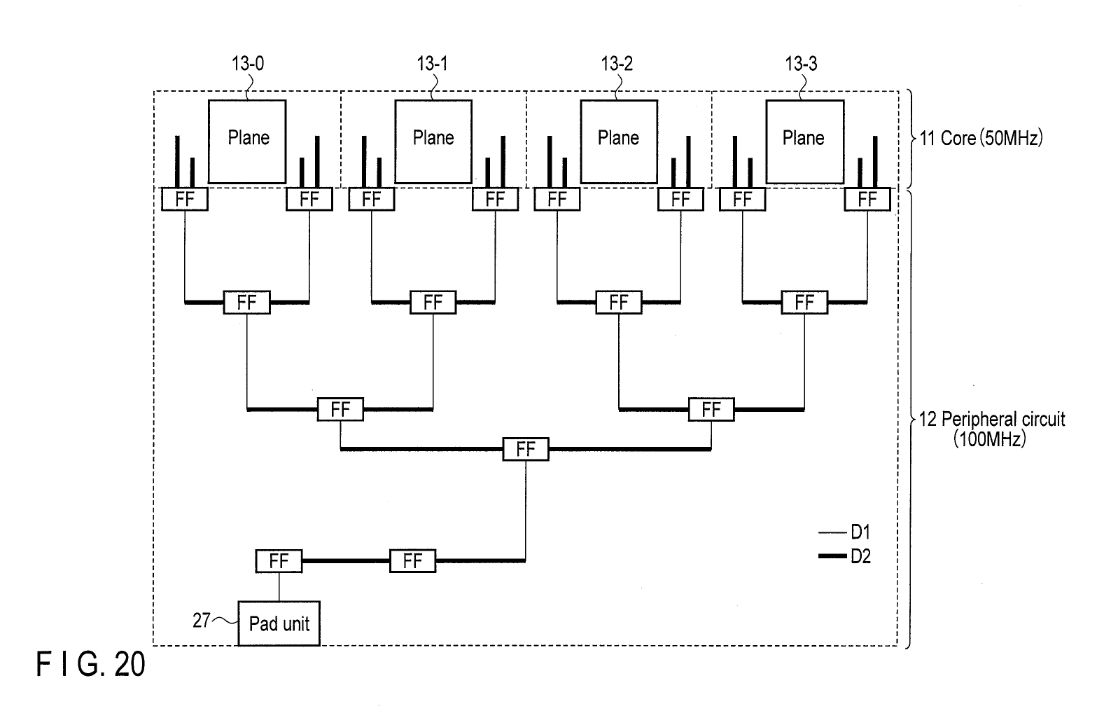

FIG. 20 is a view for explaining the arrangement of data buses of a NAND flash memory according to a comparative example. In a peripheral circuit 12 shown in FIG. 20, data buses running in the longitudinal direction are formed by an interconnect layer D1 (i.e., high-resistance interconnects), and data buses running in the lateral direction are formed by an interconnect layer D2 (i.e., low-resistance interconnects). Referring to FIG. 20, thin lines indicate interconnects (D1 interconnects) formed by interconnect layer D1, and thick lines indicate interconnects (D2 interconnects) formed by interconnect layer D2.

In this comparative example, the D1 interconnects are used as global interconnects in the longitudinal direction in the peripheral circuit 12, and cause a large wiring delay undesirable for the data buses. Especially when the size of the peripheral circuit 12 in the longitudinal direction is large, the lengths of the high-resistance D1 interconnects increase, and this is very disadvantageous to increase the speed of the data buses.

The data buses of the peripheral circuit 12 operate at a uniform speed of 100 MHz. Since, however, the very long D1 interconnects are used between flip-flops (FFs), a very large wiring delay (RC delay) occurs, and the possibility that no high-speed operation can be performed is very high. In this case, many drivers must be used in order to ensure a high-speed operation.

On the other hand, in this embodiment, the high-resistance D1 interconnects are collectively arranged in peripheral circuit 12-1, and peripheral circuit 12-1 is operated at a low speed of 50 MHz. Accordingly, accurate data transfer can be performed even when a wiring delay increases in peripheral circuit 12-1. In addition, peripheral circuit 12-2 is operated at high speed by using the low-resistance D2 interconnects. Consequently, it is possible to perform an accurate data transfer operation and increase the operating speed at the same time.

Note that the semiconductor memory device is explained by taking the three-dimensional multilayered NAND flash memory as an example in each embodiment described above, but each embodiment is not limited to this. That is, each embodiment is applicable to a planar NAND flash memory, and various semiconductor memory devices other than the NAND flash memory.

Each embodiment is not limited to the NAND flash memory which comprises U-shaped NAND strings described above. That is, each embodiment is applicable to a three-dimensional multilayered NAND flash memory comprises I-shaped type NAND strings in each of which the semiconductor layer extends directly in a perpendicular direction. Furthermore, a structure of the memory cell array is not limited as above description. A memory cell array formation may be disclosed in U.S. patent application Ser. No. 12/532,030. U.S. patent application Ser. No. 12/532,030, the entire contents of which are incorporated by reference herein.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory core including a memory cell array; and
a peripheral circuit configured to transfer data input to a pad unit to the memory core, and transfer data transferred from the memory core to the pad unit,
wherein the peripheral circuit includes a first region including a first data bus having a first wiring resistance, and a second region including a second data bus having a second wiring resistance lower than the first wiring resistance,
the first region transfers data parallel at a first operating speed, and
the second region serially transfers data at a second operating speed higher than the first operating speed.

2. The device of claim 1, further comprising a shift register located in a boundary between the first region and the second region, and configured to convert an operating speed based on two types of clocks.

3. The device of claim 2, wherein
the shift register includes a first flip-flop connected to the first data bus, and a second flip-flop connected to the second data bus,
the first flip-flop operates by using a first clock corresponding to the first operating speed, and
the second flip-flop operates by using a second clock corresponding to the second operating speed.

4. The device of claim 1, further comprising a flip-flop located in a boundary between the memory core and the peripheral circuit, and configured to transfer data from the memory core to the first data bus and operate by using a first clock corresponding to the first operating speed.

5. The device of claim 1, wherein the first operating speed is the same as an operating speed of the memory core.

6. The device of claim 1, wherein
the first data bus is formed by the same interconnect layer as that of a data line formed in the memory cell array, and
the second data bus is formed by the same interconnect layer as that of a power line formed above the data line.

7. The device of claim 1, wherein
the memory cell array includes memory strings in each of which a first select transistor, memory cell transistors, and a second select transistor are connected in series, and
the memory cell transistors are stacked on a semiconductor substrate.

8. A semiconductor memory device comprising:
a memory core including planes each including a memory cell array; and
a peripheral circuit configured to transfer data input to a pad unit to the memory core, and transfer data transferred from the memory core to the pad unit,
wherein the peripheral circuit includes a first region including first data buses provided to correspond to the planes and having a first wiring resistance, and a second region including second data buses having a second wiring resistance lower than the first wiring resistance,
the first region transfers data parallel at a first operating speed,
the second region serially transfers data at a second operating speed higher than the first operating speed, and
the second data buses have a tree structure.

9. The device of claim 8, further comprising a shift register located in a boundary between the first region and the second region, and configured to convert an operating speed based on two types of clocks.

10. The device of claim 9, wherein
the shift register includes first flip-flops connected to the first data buses, and second flip-flops connected to the second data buses,
the first flip-flops operate by using a first clock corresponding to the first operating speed, and
the second flip-flops operate by using a second clock corresponding to the second operating speed.

11. The device of claim 8, further comprising flip-flops located in a boundary between the memory core and the peripheral circuit, and configured to transfer data from the memory core to the first data buses and operate by using a first clock corresponding to the first operating speed.

12. The device of claim 8, wherein the first operating speed is the same as an operating speed of the memory core.

13. The device of claim 8, wherein
each of the first data buses is formed by the same interconnect layer as that of a data line formed in the memory cell array, and
each of the second data buses is formed by the same interconnect layer as that of a power line formed above the data line.

14. A semiconductor memory device comprising:
a memory core including a memory cell array; and
a peripheral circuit configured to transfer data input to a pad unit to the memory core, and transfer data transferred from the memory core to the pad unit,
wherein the peripheral circuit includes a first region including a first data bus, and a second region including a second data bus,
the first region transfers data parallel at a first operating speed, and is located below the memory cell array, and
the second region serially transfers data at a second operating speed higher than the first operating speed.

15. The device of claim 14, further comprising a shift register located in a boundary between the first region and the second region, and configured to convert an operating speed based on two types of clocks.

16. The device of claim 15, wherein
the shift register includes a first flip-flop connected to the first data bus, and a second flip-flop connected to the second data bus,
the first flip-flop operates by using a first clock corresponding to the first operating speed, and
the second flip-flop operates by using a second clock corresponding to the second operating speed.

17. The device of claim 14, further comprising a latch circuit located in a boundary between the memory core and the peripheral circuit, and configured to transfer data from the memory core to the first data bus.

18. The device of claim 14, wherein the first operating speed is the same as an operating speed of the memory core.

19. The device of claim 14, wherein the first region selectively transfers data by using clocks having the same frequency and different phases.

20. The device of claim 14, wherein
the memory cell array includes memory strings in each of which a first select transistor, memory cell transistors, and a second select transistor are connected in series, and
the memory cell transistors are stacked on a semiconductor substrate.
